(19) United States
(12) Patent Application Publication
(10) Pub. No.: US 2025/0047411 A1
(43) Pub. Date: Feb. 6, 2025

(54) MULTI-STAGE ENCODING AND MULTI-STAGE DECODING OF INFORMATION BITS

(71) Applicant: Huawei Technologies Co., Ltd., Shenzhen (CN)

(72) Inventor: Valerio Bioglio, Munich (DE)

(21) Appl. No.: 18/927,513

(22) Filed: Oct. 25, 2024

Related U.S. Application Data
(63) Continuation of application No. PCT/EP2022/061330, filed on Apr. 28, 2022.

(51) Int. Cl. H04L 1/00

(52) U.S. Cl. CPC H04L 1/0045; H04L 1/0042; H04L 1/0091

(57) ABSTRACT

The present disclosure relates to a multi-stage encoder comprising m sub-encoders for encoding K information bits by means of m component codes, each component code being of length N, in a codeword having a total length of mN, wherein each of m, K and N is an integer, wherein m≤N and K≤N, and wherein the encoder is configured to: store the K information bits into a message u; divide the message u into m sub-information vectors u⁽ⁱ⁾, i=1, . . . , m of length K⁽¹⁾, . . . , K^{(m)}, respectively, wherein K⁽¹⁾+ . . . +K^{(m)}=K; encode, by means of the m sub-encoders, each of the m sub-information vectors u⁽ⁱ⁾ into m sub-codewords c⁽¹⁾, . . . , c^{(m)}; map the m sub-codewords c⁽¹⁾, . . . , c^{(m)} into N symbols taken from 2^{m} constellation points of a modulation format to form a vector x; label each of the N symbols into a string of m bits; and transmit the vector x through a communication channel.

### CROSS-REFERENCE TO RELATED APPLICATIONS

This application is a continuation of International Application No. PCT/EP2022/061330, filed on Apr. 28, 2022, the disclosure of which is hereby incorporated by reference in its entirety.

### TECHNICAL FIELD

The present disclosure relates to an encoder for encoding information bits and a decoder for decoding the information bits. The encoder of this disclosure is a multi-stage encoder, and the decoder is a multi-stage decoder. The disclosure also relates to corresponding encoding and decoding methods.

### BACKGROUND

Channel codes are essential in all digital communications systems. A system for forward error correction (FEC) coding, also called a coding scheme, consists of an encoder at the transmitter side and a decoder at the receiver side. The encoder adds redundancy to the data to be transmitted, i.e. additional redundant data, and the decoder exploits this redundancy to correct transmission errors, such that the receiver obtains the transmitted data free of errors despite the noisy communication channel. For example, as shown in FIG. 1, the data u to be transmitted, termed information word, is given to the encoder, which produces the codeword x that contains redundancy. This codeword is then transmitted over a noisy communication channel, which typically introduces errors. The output vector y after the channel is provided to the decoder, which produces estimates of the transmitted codeword and of the transmitted data. The set C of possible codewords is called the code, or channel code, and the following is particularly concerned with such a code.

Polar codes are linear block codes that rely on the polarization effect (see, e.g., E. Arikan, “Channel polarization: A method for constructing capacity achieving codes for symmetric binary-input memoryless channels,” IEEE Transactions on Information Theory, vol. 55, no. 7, pp. 3051-373-7-2009), which allows to sort the bit positions of the to be transmitted data u, the bit positions also being called bit-channels, in order of reliability. As the code length grows, the polarization phenomenon influences the reliability of the bit-channels, which are either completely noisy or completely noiseless. Even more, the fraction of noiseless bit-channels tends to the channel capacity.

For finite practical code lengths, the polarization of the bit-channels is incomplete, therefore, there are bit-channels that are partially noisy. The polar encoding process comprises the classification of the bit-channels in u into two groups: the K bit-channels that will carry the information bits and are indexed by the information set I, and the N-K bit-channels that are fixed to a predefined value (usually 0) and are indexed by the frozen set F. In case of finite code lengths, the K best bit-channels, i.e. the ones with the highest reliability, are selected to form the information set, while the remaining bit-channels are frozen. Polar code decoding is usually based on Successive Cancellation (SC) decoding algorithm, which is inherently sequential. SC list decoding (SCL) is an enhanced version of SC, wherein multiple passes are performed during the decoding, while the decision is postponed to the end of the decoding process and is usually performed with the help of a cyclic redundancy check (CRC).

Bandwidth efficiency is a critical issue in the development of future wireless telecommunication systems. The use of high order modulation, together with capacity-achieving codes, is a promising direction to improve bandwidth efficiency. Bit-interleaved coded modulation (BICM) is the common technique used in the field, however, it is known to be sub-optimal over additive white Gaussian noise (AWGN) channels. Multi-level coding (MLC), in conjunction with multi-stage decoding (MSD), looks more promising, however it is more complex and more sensitive to code design. By construction, polar codes are the best candidates as component codes for a MLC/MSD system. Multi-level polar codes (MLPC) have been proposed along with a long list of design principles. A multilevel polar code (MLPC) of length mN is a multilevel code with length-N component polar codes over an 2^{m}-ary constellation. Component polar codes design can be performed according to polarization effect of virtual channels at each decoding level. This effect depends on the modulation scheme adopted in the transmission. It has been proved that MLPC provide better performance if set-partitioning (SP) labelling is used in the high-order modulation scheme.

De-mapping of MLPC over quadrature amplitude modulation (QAM) suffers of two main drawbacks. First, the sub-constellation of a partially decoded symbol depends on the decisions taken on the previously decoded bits. As a consequence, each symbol has a specific sub-constellation, which should be stored in a memory, while the number of sub-constellations doubles at each decoding level. Second, the complexity of the log-likelihood-ratio (LLR) calculation depends on the number of constellation symbols, and increases exponentially with the modulation order. These issues are not specific to MLPC decoding, but they are common to every MLC/MSD system.

Furthermore, the current SP labelling for QAM constellation requires to store multiple sub-constellations at the receiver or decoder. At every decoding level, the decision taken on a bit deletes half of the constellation points of the QAM constellation for the next decoding step, however, the deleted constellation points depend on the decision taken. Moreover, finding the closest constellation point for a received symbol requires the calculation of an Euclidean distance between the symbol and every constellation point.

Thus, there is a need for an improved encoder for encoding information bits and an improved decoder for decoding the information bits.

### SUMMARY

The present disclosure has the objective to provide for such an improved encoder and decoder. In particular, an objective is to overcome the above mentioned drawbacks.

These and other objectives are achieved by the solution provided in the enclosed independent claims. Advantageous implementations are further defined in the dependent claims.

In order to better understand the solution of the present disclosure, in the following, some theoretical considerations are given.

The functioning of an example of a MLC/MSD system with m levels is depicted in FIG. 2. Such a system is composed of m component codes of length N, resulting in an overall code of length mN bits, which is transmitted through N symbols. At the transmitter side, the K information bits stored in the message u (data to be transmitted) are divided into m sub-information vectors of lengths K⁽¹⁾, K⁽²⁾, . . . , K^{(m)} respectively, with K⁽¹⁾+K⁽²⁾+ . . . +K^{(m)}=K, wherein each sub-information vector is encoded through one of the m component codes. It is worth noticing that lower levels are less reliable and are more prune to transmission errors, hence, K^{(l)}≤K^{(l+1)}. Notably, the design of the multi-level code is out of the scope of this disclosure. At level l, the (K^{(l)}, N) component code takes as an input the K^{(l)} sub-information bits and encodes the sub-information bits into a sub-codeword c^{(l)} that is composed of N bits. If the component codes are polar codes, the resulting MLC is termed a multi-level polar code (MLPC), and the K^{(l)} sub-information bits are stored in a sub-input vector u^{(l)} of length N before being encoded. At the end of the multi-level encoding stage, the m sub-codeword c⁽¹⁾, c⁽²⁾, . . . , c^{(m)} are mapped to N symbols taken from the 2^{m} constellation points of the modulation. Each symbol represents m bits, taken across the m sub-codewords as follows. The i-th encoded symbol is composed by appending the i-th encoded bits of each sub-codeword. The first bit is the i-th encoded bit of sub-codeword c⁽¹⁾, the second bit is the i-th encoded bit of sub-codeword c⁽²⁾, and so on. As a result, a vector x composed of N constellation points is obtained and then transmitted through the noisy communication channel.

At the receiver side, a multi-stage decoding (MSD) is performed by decoding component codes sequentially from the first to the last level, and adjusting the constellation points available at a certain level on the basis of the previously decoded component codes. To begin with, a vector y composed of N symbols is received from the channel. Each symbol represents a constellation point that has been altered by the channel noise. This received vector y is initially decoded by the first level decoder of the MSD system. Log-likelihood-ratios (LLRs), which are used by the component code decoder, are calculated on the basis of the received vector y. In practice, the constellation points are divided into two sets [symbol] and [symbol] , collecting the constellation points having a 0 and a 1 in the first position, respectively. In this way, if yᵢ represents the i-th symbol of vector y, its LLR [symbol] , namely the i-th LLR that is passed to the first level decoder, is calculated as:

$${ℓ}_{i}^{( 1 )} = L L R ( {y}_{i} ) = log \frac{ℙ ( {y}_{i} \vert p ϵ {𝒫}_{0}^{( 1 )} )}{ℙ ( {y}_{i} \vert p ϵ {𝒫}_{1}^{( 1 )} )} .$$

The LLR vector [symbol] is then given to the first level component code decoder. The component code decoder outputs a binary vector û⁽¹⁾, which represents the estimation of the first K⁽¹⁾ message bits (or an estimation of the input vector u⁽¹⁾ for MLPC). A binary vector û⁽¹⁾ is then encoded through the first level encoder to calculate ĉ⁽¹⁾, representing an estimation of the first level codeword c⁽¹⁾. The bits composing such an estimated codeword are used to reduce the constellation size for the next decoding step. In practice, if a symbol has been decoded as a 0, its new constellation is [symbol] , while the constellation is [symbol] if the symbol has been decoded as a 1. For the next step decoding, the constellation points will be divided again into two subset, collecting the constellation points having a 0 and a 1 in the second position. In this case, however, the subsets depend also on the decision taken at the first level of decoding. In general, at decoding level l, the subsets of the two constellation points depend on the symbol yᵢ, hence they are termed as [symbol] and [symbol] , respectively. Now, the multi-stage decoding technique is repeated at every decoding level. At level l, LLRs are calculated as:

$${ℓ}_{i}^{( 1 )} = log \frac{ℙ ( {y}_{i} \vert p ϵ {𝒫}_{0}^{( l , i )} )}{ℙ ( {y}_{i} \vert p ϵ {𝒫}_{1}^{( l , i )} )} = log \frac{{\sum }_{{p}_{0} ϵ {𝒫}_{0}^{( l , i )}} {e}^{- \frac{{‖ {y}_{i} - {p}_{0} ‖}^{2}}{2 {σ}^{2}}}}{{\sum }_{{p}_{1} ϵ {𝒫}_{1}^{( l , i )}} {e}^{- \frac{{‖ {y}_{i} - {p}_{1} ‖}^{2}}{2 {σ}^{2}}}} ≅ \frac{{‖ {y}_{i} - {\hat{p}}_{1} ‖}^{2} - {‖ {y}_{i} - {\hat{p}}_{0} ‖}^{2}}{2 {σ}^{2}} ,$$

where σ² represents the AWGN channel variance and \hat{p}ₐ represents the closest point to yᵢ for constellation [symbol] . At the end of the last decoding stage, binary vectors û⁽¹⁾, û⁽²⁾, . . . , û^{(m)} are combined to obtain an estimation m of the transmitted message.

A MLC/MSD system with m levels can be naturally modulated through a QAM constellation of 2^{m} points. Bi-dimensional QAM constellations with SP labeling have been widely employed in wireless and optical transmission due to their good noise tolerance. SP labeling permits to increase the average Euclidean distance among the constellation points at every level, enhancing the spectral efficiency. A 2^{m}-QAM bi-dimensional constellation, where m is even, is a subset of the Cartesian plane formed by points on a grid of size 2^{m/2}×2^{m/2}. This grid is usually centered in the intersection of the axis, while the points have vertical and horizontal distance of 2 from their closest neighbors. SP labeling has been originally proposed by G. Ungerboeck in “Trellis-coded modulation with redundant signal sets Part I: Introduction,” IEEE Commun. Mag., vol. 25, no. 2, pp. 5-11, February 1987, and consists of dividing the constellation points into two subsets, one assigned to a bit value of 0 and the other to a bit value of 1, such that the minimum distance between two points in the same sub-constellation is minimized. Each sub-constellation is divided again into two subset, following the same strategy of minimum distance maximization. The process is repeated until the sub-constellation is formed by a single point. A scheme to perform SP labeling of regular constellations, including QAM, is provided by G. D. Forney in “Coset codes. I. Introduction and geometrical classification,” IEEE Trans. Inf. Theory, vol. IT-34, no. 5, pp. 1123-1151-9-1988.

Based on the above, according to a first aspect, the disclosure relates to a multi-stage encoder comprising m sub-encoders for encoding K information bits by means of m component codes, each component code being of length N, in a codeword having a total length of mN, wherein each of m, K and N is an integer, wherein m≤N and K≤N, and wherein the encoder is configured to:
store the K information bits into a message u;
divide the message u into m sub-information vectors u⁽ⁱ⁾, i=1, . . . , m of length K⁽¹⁾, . . . , K^{(m)}, respectively, wherein K⁽¹⁾+ . . . +K^{(m)}=K;
encode, by means of the m sub-encoders, each of the m sub-information vectors u⁽ⁱ⁾ into m sub-codewords c⁽¹⁾, . . . , c^{(m)};
map the m sub-codewords c⁽¹⁾, . . . , c^{(m)} into N symbols taken from 2^{m} constellation points of a modulation format to form a vector x;
label each of the N symbols into a string of m bits; and
transmit the vector x through a communication channel.

For example, this provides the advantage that a low-complexity de-mapper at the decoder side can be implemented. Moreover, this provides the advantage that the spectral efficiency is enhanced. The labelling can be a set-partitioning labelling. This provides the advantage that a good noise tolerance is achieved.

In a preferred embodiment, the encoder is configured to label each of the N symbols into the string of m bits as follows: if a first constellation point A has coordinates (α, β),
determine a sign S_{A} of the first constellation point A;
assign a first bit value to a label of the point A as 0 or 1 depending on the sign S_{A}; then, for i=1, . . . , m−1
   determine coordinates of a second constellation point Aⁱ=(αⁱ, βⁱ) on the basis of i+1 and a i^{th} bit value, wherein the 1^{st} bit value is the first bit value;
   determine a sign S_{Ai} of the second constellation point Aⁱ;
   determine a (i+1)^{th} bit value on the basis of sign S_{Ai}; and
   assign the (i+1)^{th} bit value to the label of the point A.

This provides the advantage that the spectral efficiency is enhanced.

In an implementation form of the first aspect, the coordinates (α, β) and (αⁱ, βⁱ) are Cartesian coordinates.

This provides that advantage that well-known coordinates can easily be implemented.

In an implementation form of the first aspect, the encoder is further configured to determine the sign S_{A} of the first constellation point A on the basis of the following formula:

$${s}_{A} = sign ( {( {[ β + α + d ]}_{2 d} - d )}^{2} + {( {[ β - α ]}_{2 d} - d )}^{2} - {( {[ β + α ]}_{2 d} - d )}^{2} - {( {[ β - α + d ]}_{2 d} - d )}^{2} ) ,$$

wherein d is a distance of the constellation points.

This provides the advantage that a simple formula can easily be implemented.

In implementation form of the first aspect, for i=1, the encoder is configured to calculate the coordinates (α¹, β¹) of the second constellation point A¹ on the basis of the following formula:

$${α}^{1} = \{ \begin{matrix}\frac{α + β}{2} if a = 0 , i is even \\ \frac{α + β}{2} if a = 0 , i is odd \\ \frac{α - β}{2} if a = 1 , i is even \\ \frac{α + β}{2} if a = 1 , i is odd\end{matrix} , \qquad {β}^{1} = \{ \begin{matrix}\frac{β - α + d}{2} if a = 0 , i is even \\ \frac{β - α - d}{2} if a = 0 , i is odd \\ \frac{α + β + d}{2} if a = 1 , i is even \\ \frac{α + β - d}{2} if a = 1 , i is odd\end{matrix}$$

wherein a represents a value of a previously assigned bit.

This provides the advantage that a simple formula can easily be implemented.

In an implementation form of the first aspect, the constellation points are of a 2^{m} quadrature amplitude modulation bi-dimensional modulation format, where m is an even number.

This provides the advantage that a good noise tolerance can be achieved.

According to a second aspect, the disclosure relates to a multi-stage decoder comprising m sub-decoders. The decoder is configured to:
receive, over a communication channel, a vector y comprising a set of N symbols, wherein each of m and N is an integer and m≤N, wherein each received symbol yᵢ^{(l)} corresponds to one of a set of constellation points of a bi-dimensional modulation format, wherein the set of constellation points is divided into two subsets of constellation points including a first subset assigned to a bit of value 0 and a second subset assigned to a bit of value 1, such that a minimum distance d in the same subset is maximized, and wherein the vector y has coordinates (α, β) and components yᵢ^{(l)}, i=1, . . . , N, and l=1, . . . , m;
determine a log-likelihood-ratio [symbol] on the basis of a respective received symbol yᵢ^{(l)};
determine a bit value on the basis of the log-likelihood-ratio [symbol] by means of a 1-level sub-decoder;
obtain a new symbol yᵢ^{(l+1)} for each symbol yᵢ^{(l)} on the basis of the bit value and by performing a transformation on the symbol yᵢ^{(l)}, wherein the transformation comprises a rotation and a shift;
determine a next log-likelihood-ratio [symbol] on the basis of the new symbol yᵢ^{(l+1)};
determine a next bit value on the basis of the next log-likelihood-ratio [symbol] ; and
decode the vector y on the basis of the bit value and the next bit value.

This provides the advantage that the complexity of the calculation of the log-likelihood-ratio is reduced. Moreover, this provides the advantage that the decoder does not have to keep track of sub-constellation points of every decoding level, but simply modify the received symbol, while keeping always the same constellation. Moreover, the number of constellation points is halved at every decoding level.

In an implementation form of the second aspect, the constellation points are of a 2^{m} quadrature amplitude modulation bi-dimensional modulation format, where m is an even number.

This provides the advantage that a good noise tolerance can be achieved.

In an implementation form of the second aspect, the decoder is configured to generate a decision grid as a Cartesian plane partition, wherein a center of a square of the decision grid represents a constellation symbol.

In an implementation form of the second aspect, the decoder is further configured to calculate the new symbol yᵢ^{(l+1)} on the basis of the received symbol yᵢ^{(l)}=(α, β), wherein (α, β) are coordinates of the received symbol yᵢ^{(l)},
wherein, if l is odd, then:
   If the received symbol yᵢ^{(l)} has been decoded as a 0, then

$${y}_{i}^{( l + 1 )} = ( \frac{β + α}{2} , \frac{β - α + d}{2} ) ;$$

If the received symbol yᵢ^{(l)} has been decoded as a 1, then

$${y}_{i}^{( l + 1 )} = ( \frac{α - β}{2} , \frac{α + β + d}{2} ) ,$$

and
wherein, if l is even, then:
   If the received symbol yᵢ^{(l)} has been decoded as a 0, then

$${y}_{i}^{( l + 1 )} = ( \frac{β + α}{2} , \frac{β - α - d}{2} ) ;$$

If the received symbol yᵢ^{(l)} has been decoded as a 1, then

$${y}_{i}^{( l + 1 )} = ( \frac{α - β}{2} , \frac{α + β - d}{2} ) .$$

In an implementation form of the second aspect, the decoder is further configured to calculate the log-likelihood-ratio [symbol] as:

$${ℓ}_{i}^{( l )} ≅ \frac{{{( {[ β + α + d ]}_{2 d} - d )}^{2} + {( {[ β - α ]}_{2 d} - d )}^{2} - {[ β + α ]}_{2 d} - d )}^{2} - {( {[ β - α + d ]}_{2 d} - d )}^{2}}{4 {σ}^{2}} ,$$

wherein [·]_{2d} represents a modulo 2d truncation and σ represents a channel variance.

This provides the advantage that the complexity of the calculation of the log-likelihood-ratio is reduced.

According to a third aspect, the disclosure relates to a method for a multi-stage encoder comprising m sub-encoders for encoding K information bits by means of m component codes, each of length N, in a codeword having a total length of mN, wherein each of m, K and N is an integer, wherein m≤N and K≤N. The method comprises:
storing the K information bits into a message u;
dividing the message u into m sub-information vectors u⁽ⁱ⁾, i=1, . . . , m of length K⁽¹⁾, . . . , K^{(m)}, respectively, wherein K⁽¹⁾+ . . . +K^{(m)}=K;
encoding, by means of the m sub-encoders, each of the sub-information vectors u⁽ⁱ⁾ into m sub-codewords c⁽¹⁾, . . . , c^{(m)};
mapping the m sub-codewords c⁽¹⁾, . . . , c^{(m)} into N symbols taken from 2^{m} constellation points of a modulation format to form a vector x;
labelling each of the N symbols into a string of m bits; and
transmitting the vector x through a communication channel.

In an implementation form of the third aspect, the step of labelling each of the N symbols into a string of m bits comprises:
if a first constellation point A has coordinates (α, β),
   determining a sign S_{A} of the first constellation point A;
   assigning a first bit value to a label of the point A as 0 or 1 depending on the sign S_{A}; then, for i=1, . . . , m−1
      determining coordinates of a second constellation point Aⁱ=(αⁱ, βⁱ) on the basis of i+1 and a i^{th} bit value, wherein the 1^{st} bit value is the first bit value;
      determining a sign S_{Ai} of the second constellation point Aⁱ;
      determining a (i+1)^{th} bit value on the basis of sign S_{Ai};
      assigning the (i+1)^{th} bit value to the label of the point A.

According to a fourth aspect, the disclosure relates to a method for a multi-stage decoder comprising m sub-decoders. The method comprises:
receiving, over a communication channel, a vector y comprising a set of N symbols, wherein each of m and N is an integer and m≤N, wherein each received symbol yᵢ^{(l)} corresponds to one of a set of constellation points of a bi-dimensional modulation format, wherein the set of constellation points is divided into two subsets of constellation points including a first subset assigned to a bit of value 0 and a second subset assigned to a bit of value 1, such that a minimum distance d in the same subset is maximized, wherein the vector y has coordinates (α, β) and components yᵢ^{(l)}, i=1, . . . , N, and l=1, . . . , m;
determining a log-likelihood-ratio [symbol] on the basis of a respective received symbol yᵢ^{(l)};
determining a bit value on the basis of the log-likelihood-ratio [symbol] by means of a l-level sub-decoder;
obtaining a new symbol yᵢ^{(l+1)} for each symbol yᵢ^{(l)} on the basis of the bit value and by performing a transformation on the symbol yᵢ^{(l)}, wherein the transformation comprises a rotation and a shift;
determining a next log-likelihood-ratio [symbol] on the basis of the new symbol yᵢ^{(l+1)};
determining a next bit value on the basis of the next log-likelihood-ratio [symbol] ; and
decoding the vector y on the basis of the bit value and the next bit value.

According to a fifth aspect, the disclosure relates to a computer program comprising instructions which, when the computer program is executed by a computer, cause the computer to perform the method according to the third aspect or fourth aspect.

It has to be noted that all devices, elements, units and means described in the present application could be implemented in the software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof.

### BRIEF DESCRIPTION OF THE DRAWINGS

The above described aspects and implementation forms of the present disclosure will be explained in the following description of specific embodiments in relation to the enclosed drawings, in which:

FIG. 1 shows a schematic representation of an exemplary system comprising an encoder and a decoder;

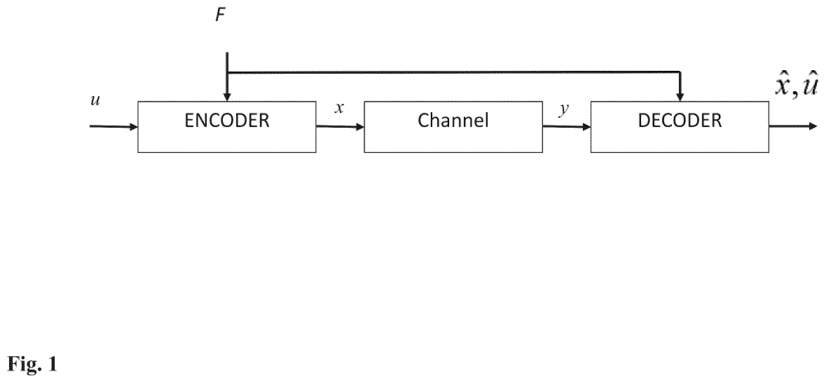

FIG. 2 shows a schematic representation of an exemplary system comprising an encoder and a decoder;

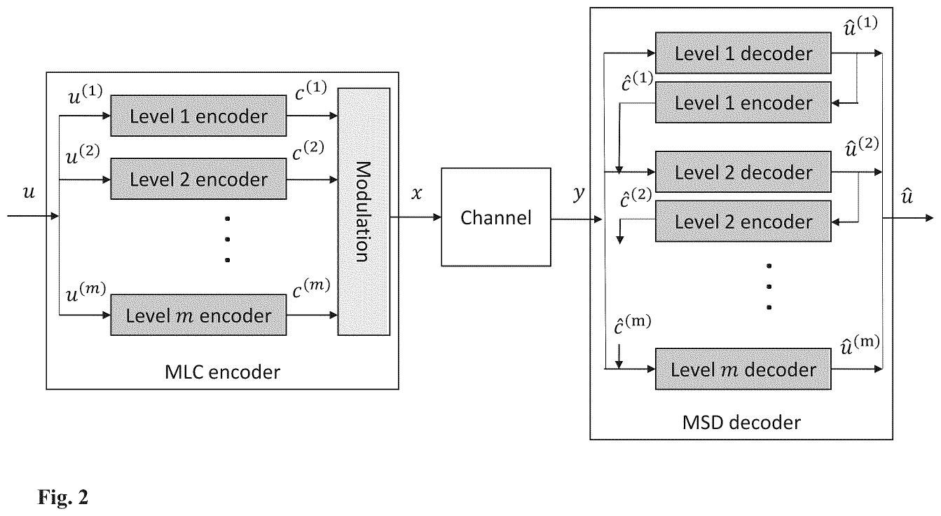

FIG. 3 shows a schematic representation of a system comprising an encoder and a decoder according to an embodiment of this disclosure;

FIG. 4 shows a labelling for a constellation according to an embodiment of this disclosure;

FIG. 5 shows a labelling and a de-modulation example according to an embodiment of this disclosure;

FIG. 6 shows a schematic representation of a checkerboard structure of a decision grid with constellation points according to an embodiment of this disclosure;

FIG. 7 shows boundaries of different constellations over the decision grid according to an embodiment of this disclosure;

FIG. 8 shows a labelling for a constellation according to an embodiment of this disclosure;

FIG. 9 shows a labelling for a constellation according to an embodiment of this disclosure;

FIG. 10 shows a method for a multi-stage encoder according to an embodiment of this disclosure; and

FIG. 11 shows a method for a multi-stage decoder according to an embodiment of this disclosure.

### DETAILED DESCRIPTION OF ILLUSTRATIVE EMBODIMENTS

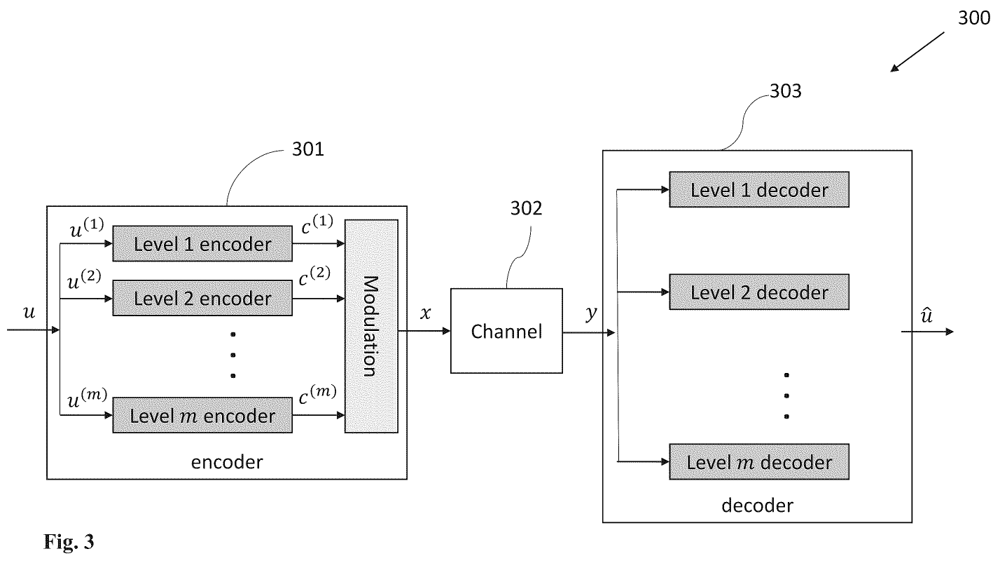

FIG. 3 shows a schematic representation of a system 300 comprising an encoder 301 and a decoder 303 according to embodiments of this disclosure, respectively.

The multi-stage encoder 301 comprises m sub-encoders for encoding K information bits by means of m component codes. Each component code is of length N, in a codeword having a total length of mN, wherein each of m, K and N is an integer, and wherein m≤N and K≤N.

The encoder 301 is configured to store the K information bits into a message u. Further, the encoder 301 is configured to divide the message u into m sub-information vectors u⁽ⁱ⁾, i=1, . . . , m of length K⁽¹⁾, . . . , K^{(m)}, respectively, wherein K⁽¹⁾+ . . . +K^{(m)}=K. Then, the encoder 301 is configured to encode, by means of the m sub-encoders, each of the m sub-information vectors u⁽ⁱ⁾ into m sub-codewords c⁽¹⁾, . . . , c^{(m)}, and to map the m sub-codewords c⁽¹⁾, . . . , c^{(m)} into N symbols taken from 2^{m} constellation points of a modulation format to form a vector x. Then, the encoder 301 is configured to label each of the N symbols into a string of m bits. Finally, the encoder 310 is configured to transmit the vector x through a communication channel 302.

The encoder 301 may be further configured to label each of the N symbols into the string of m bits as follows: if a first constellation point A has coordinates (α, β), the encoder 301 is configured to determine a sign S_{A} of the first constellation point A, and to assign a first bit value to a label of the point A as 0 or 1 depending on the sign S_{A}. Then, for i=1, . . . , m−1, the encoder 301 is configured to determine coordinates of a second constellation point Aⁱ=(αⁱ, βⁱ) on the basis of i+1 and a i^{th} bit value, wherein the 1^{st} bit value is the first bit value, to determine a sign S_{Ai} of the second constellation point Aⁱ, to determine a (i+1)^{th} bit value on the basis of sign S_{Ai}, and to assign the (i+1)^{th} bit value to the label of the point A.

In order to enable a low-complexity de-mapping at the receiver side, specifically the decoder 303, a labelling method can be used at the transmitting side, specifically the encoder 301 side. For example, given a constellation point, in the following, it is described how to assign to the constellation point a string of m bits. In particular, given a constellation point A with Cartesian coordinates (α, β), its first bit value is assigned by checking the sign of A:

$${s}_{A} = sign ( {( {[ β + α + d ]}_{2 d} - d )}^{2} + {( {[ β - α ]}_{2 d} - d )}^{2} - {( {[ β + α ]}_{2 d} - d )}^{2} - {( {[ β - α + d ]}_{2 d} - d )}^{2} )$$

In the above formula, if s_{A} is positive, the assigned bit is a 0, otherwise it is a 1. This formula is valid for all the bit levels.

Next, for i=1, the coordinates of the second constellation point A¹ can be calculated on the basis of both the bit value and the position of next bit to be calculated. If i represents the next bit position and a represents the value of the previous calculated bit, the Cartesian coordinates (α¹, β¹) of point A¹ can be calculated as follows:

$${α}^{1} = \{ \begin{matrix}\frac{α + β}{2} if a = 0 , i is even \\ \frac{α + β}{2} if a = 0 , i is odd \\ \frac{α - β}{2} if a = 1 , i is even \\ \frac{α + β}{2} if a = 1 , i is odd\end{matrix} , \qquad {β}^{1} = \{ \begin{matrix}\frac{β - α + d}{2} if a = 0 , i is even \\ \frac{β - α - d}{2} if a = 0 , i is odd \\ \frac{α + β + d}{2} if a = 1 , i is even \\ \frac{α + β - d}{2} if a = 1 , i is odd\end{matrix}$$

After moving, the sign s_{A1} is evaluated, in order to assign the value of the next bit, and then point A² is calculated, and so on. The process ends when all the l bit values are assigned.

To summarize, the proposed SP labelling for QAM constellation permits a low-complexity de-mapping for MLC decoding. The labelling can be stored for future transmissions.

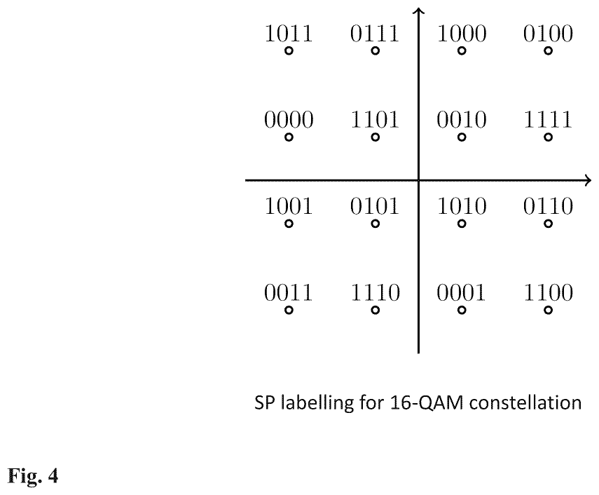

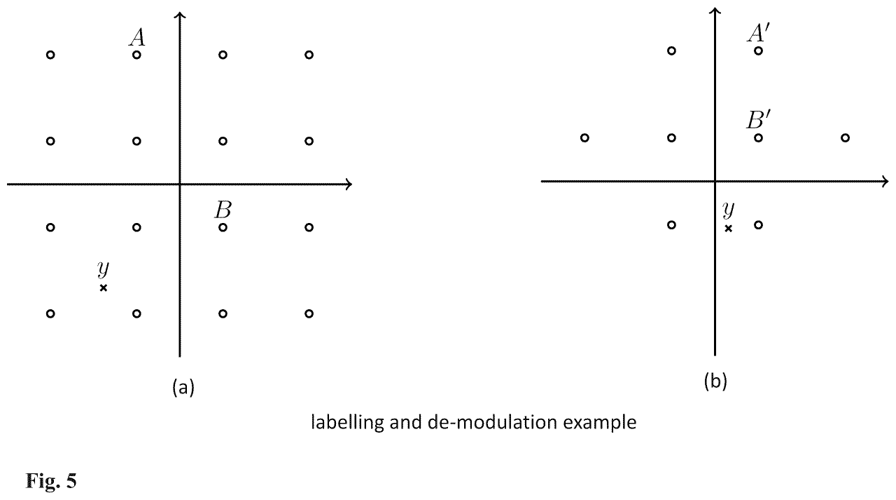

As an example, let us take a 16-QAM constellation and use the above-described method to retrieve the labelling depicted in FIG. 4. To begin with, let us consider the constellation point A depicted in FIG. 5(a), which has Cartesian coordinates

$$( - \frac{d}{2} , \frac{3}{2} d ) ,$$

where d is the distance of the constellation points. For this point:

$${s}_{A} = sign ( {( {[ \frac{3}{2} d - \frac{d}{2} + d ]}_{2 d} - d )}^{2} + {( {[ \frac{3}{2} d + \frac{d}{2} ]}_{2 d} - d )}^{2} - {( {[ \frac{3}{2} d - \frac{d}{2} ]}_{2 d} - d )}^{2} - {( {[ \frac{3}{2} d + \frac{d}{2} + d ]}_{2 d} - d )}^{2} ) = + 1$$

So the first bit is a 0. Afterwards, the encoder 301 can be configured to calculate the Cartesian coordinates of A¹. In this case, a=0 and i=2, hence

$${A}^{1} = ( {α}^{1} , {β}^{1} ) = ( \frac{α + β}{2} , \frac{β - α + d}{2} ) = ( \frac{d}{2} , \frac{3}{2} d ) .$$

This point is depicted in FIG. 5(b). In this FIG. 5(b), the achievable constellation points are only the 8 depicted, since each constellation point can be reached by two different 16-QAM constellation points. Now, in order to calculate the second bit of the labelling, the encoder 301 can be configured to calculate:

$${s}_{A 1} = sign ( {( {[ \frac{3}{2} d + \frac{d}{2} + d ]}_{2 d} - d )}^{2} + {( {[ \frac{3}{2} d - \frac{d}{2} ]}_{2 d} - d )}^{2} - {( {[ \frac{3}{2} d + \frac{d}{2} ]}_{2 d} - d )}^{2} - {( {[ \frac{3}{2} d - \frac{d}{2} + d ]}_{2 d} - d )}^{2} ) = - 1$$

So the second bit is 1. In order to calculate the Cartesian coordinates of A², a=1 and i=3, the encoder 301 can be configured to calculate:

$${A}^{2} = ( {α}^{2} , {β}^{2} ) = ( \frac{{α}^{1} - {β}^{1}}{2} , \frac{{α}^{1} + {β}^{1} + d}{2} ) = ( - \frac{d}{2} , \frac{d}{2} ) .$$

Proceeding in this way, point A is labelled as 0111, as confirmed in FIG. 4. Similarly, considering the constellation point B depicted in FIG. 5(a), having Cartesian coordinates

$$( \frac{d}{2} , - \frac{d}{2} ) :$$

$${s}_{B} = sign ( {( {[ - \frac{d}{2} + \frac{d}{2} + d ]}_{2 d} - d )}^{2} + {( {[ - \frac{d}{2} - \frac{d}{2} ]}_{2 d} - d )}^{2} - {( {[ - \frac{d}{2} + \frac{d}{2} ]}_{2 d} - d )}^{2} - {( {[ - \frac{d}{2} - \frac{d}{2} + d ]}_{2 d} - d )}^{2} ) = - 1$$

So, having a=1 and i=2, then:

$${B}^{1} = ( {α}^{1} , {β}^{1} ) = ( \frac{α - β}{2} , \frac{α + β + d}{2} ) = ( \frac{d}{2} , \frac{d}{2} )$$

as depicted in FIG. 5(b). To find the value of the second bit, the encoder 301 can be configured to calculate:

$${s}_{B 1} = sign ( {( {[ \frac{d}{2} + \frac{d}{2} + d ]}_{2 d} - d )}^{2} + {( {[ \frac{d}{2} - \frac{d}{2} ]}_{2 d} - d )}^{2} - {( {[ \frac{d}{2} + \frac{d}{2} ]}_{2 d} - d )}^{2} - {( {[ \frac{d}{2} - \frac{d}{2} + d ]}_{2 d} - d )}^{2} ) = + 1$$

So, the second bit is a 0. Since a=0 and i=3:

$${B}^{2} = ( {α}^{2} , {β}^{2} ) = ( \frac{{α}^{1} + {β}^{1}}{2} , \frac{{β}^{1} - {α}^{1} - d}{2} ) = ( \frac{d}{2} , - \frac{d}{2} ) .$$

Proceeding with the proposed method, the point B is labelled as 1010.

Once the vector x is obtained, it is transmitted over the communication channel 302 to the multi-stage decoder 303.

The multi-stage decoder 303 comprises m sub-decoders. The decoder 303 is configured to receive, over the communication channel 302, a vector y comprising a set of N symbols, wherein each of m and N is an integer and m≤N. Each received symbol yᵢ^{(l)} corresponds to one of a set of constellation points of a bi-dimensional modulation format, wherein the set of constellation points is divided into two subsets of constellation points including a first subset assigned to a bit of value 0 and a second subset assigned to a bit of value 1, such that a minimum distance d in the same subset is maximized, and wherein the vector y has coordinates (α, β) and components yᵢ^{(l)}, i=1, . . . , N, and l=1, . . . , m.

The decoder 303 is further configured to determine a log-likelihood-ratio [symbol] on the basis of a respective received symbol yᵢ^{(l)}, and to determine a bit value on the basis of the log-likelihood-ratio [symbol] by means of a l-level sub-decoder. Further, the decoder 303 is configured to obtain a new symbol yᵢ^{(l+1)} for each symbol yᵢ^{(l)} on the basis of the bit value and by performing a transformation on the symbol yᵢ^{(l)}, wherein the transformation comprises a rotation and a shift. Then, the decoder 303 is configured to determine a next log-likelihood-ratio [symbol] on the basis of the new symbol yᵢ^{(l+1)}, and to determine a next bit value on the basis of the next log-likelihood-ratio [symbol] . Finally, the decoder 303 is configured to decode the vector y on the basis of the bit value and the next bit value.

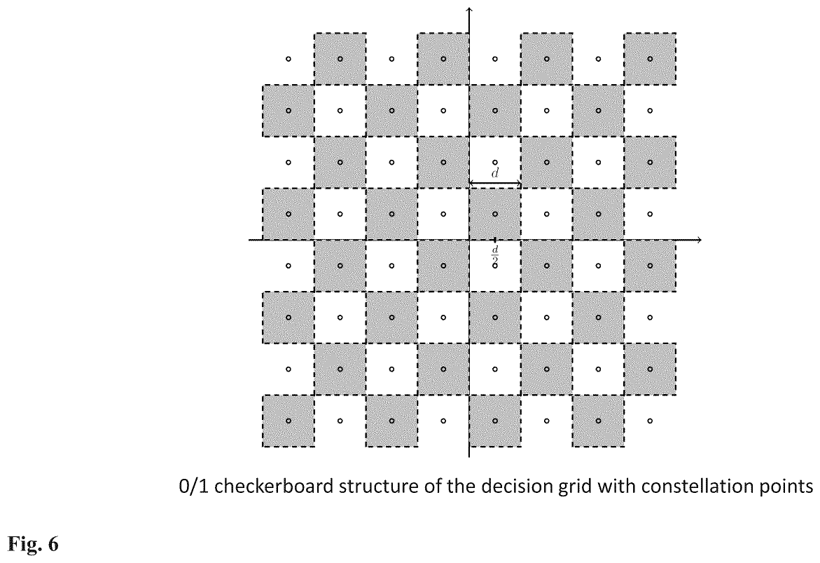

The above proposed SP labelling strategy reduces the LLRs calculation complexity at the decoder 303 (or generally the receiver side). The same “constellation” can be kept at every decoding level, while the received symbols are altered on the basis of the decisions taken during the decoding. In practice, after the decoding of a component code of a certain level, instead of deleting half of the constellation points, it is proposed to “move” the point representing the received symbol. In this way, the decoder 303 may not have to keep track of the sub-constellation points of every decoding level, but may simply modify the received symbol on the basis of the decoding result, while keeping always the same constellation. Of course, the number of constellation points is halved at every decoding level, however, only the boundary of the constellation changes, while the overall structure of the 0/1 checkboard structure remains the same (see FIG. 6).

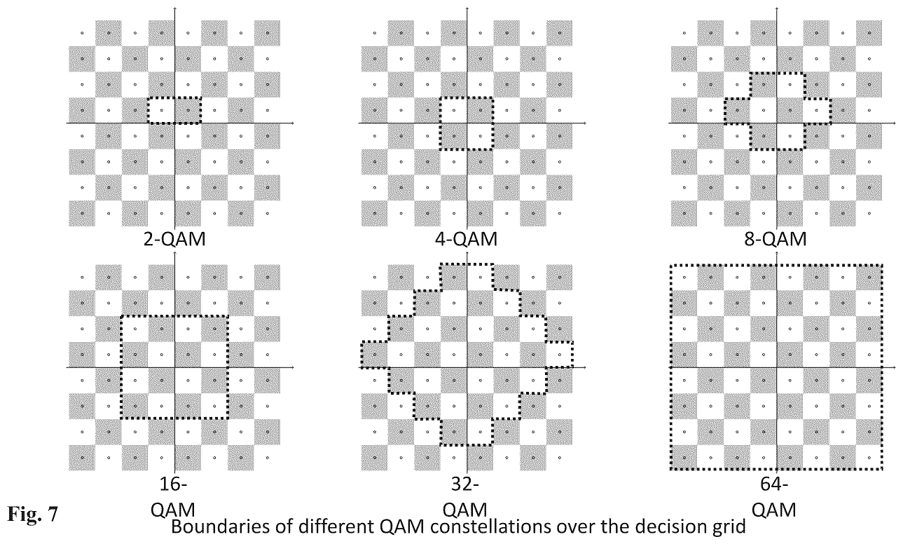

To start with, a decision grid may be created, namely a Cartesian plane partition having a checkboard structure. The centre of a square of the grid may represent a constellation symbol, which can be used to find the nearest constellation point. The structure of the proposed decision grid is depicted in FIG. 6, where dark grey area represent 0 and white area represent 1. Moreover, in FIG. 7, the boundaries of different QAM constellations, or alternatively for different decoding levels, are highlighted: the boundary of a level l constellation is given by a 2^{m-l} QAM for a m levels MLC.

Starting from a 2^{m}-QAM bi-dimensional constellation, where m is even, with a minimum distance d, the following described how to move the received symbol yᵢ=yᵢ⁽¹⁾ at first level in order to obtain the new symbol yᵢ⁽²⁾ for the decoding of the second level code. Moving rules depend on the decision taken by the decoder 303:
If the symbol yᵢ⁽¹⁾ has been decoded as a 0, the point is first scaled by multiplying it by

$$\frac{1}{\sqrt{2}} ,$$

rotated clockwise by 45° and, when, shifted upwards by d/2.
If the symbol yᵢ⁽¹⁾ has been decoded as a 1, the point is first scaled by multiplying it by

$$\frac{1}{\sqrt{2}} ,$$

rotated counter clockwise by 45° and, then, shifted upwards by d/2.

Following these rules, each component of the received vector y=y⁽¹⁾ can be moved, obtaining a new vector y⁽²⁾ that can be used in the calculation of the LLRs for the decoding of the second level code. After the decoding, the points in y⁽²⁾ will be moved again to obtain the vector y⁽³⁾ to be used in next decoding step. The rules for the second level decoding are slightly different: overall, moving rules for even and odd levels are different. However, for levels of the same parity, the rules are always the same. In this case:
If the symbol yᵢ(2) has been decoded as a 0, the point is first scaled by multiplying it by

$$\frac{1}{\sqrt{2}} ,$$

shifted rightward by d/2, then, shifted downwards by d/2 and, finally, rotated clockwise by 45°.
If the symbol yᵢ⁽²⁾ has been decoded as a 1, the point is first scaled by multiplying it by

$$\frac{1}{\sqrt{2}} ,$$

shifted leftward by d/2, then shifted downwards by d/2 and, finally, rotated counterclockwise by 45°.

To summarize, the general rules to calculate the point or new symbol yᵢ^{(l+1)} from the previous level point or respective received symbol yᵢ^{(l)}=(α, β) are the following:

If l is odd, then:
If the symbol yᵢ^{(l)} has been decoded as a 0, the point is first scaled by multiplying it by

$$\frac{1}{\sqrt{2}} ,$$

rotated clockwise by 45° and, then, shifted upwards by d/2, namely the new symbol is given by:

$${y}_{i}^{( l + 1 )} = ( \frac{β + α}{2} , \frac{β - α + d}{2} ) .$$

If the symbol yᵢ^{(l)} has been decoded as a 1, the point is first scaled by multiplying it by

$$\frac{1}{\sqrt{2}} ,$$

rotated counterclockwise by 45° and, then, shifted upwards by d/2, namely the new symbol is given by:

$${y}_{i}^{( l + 1 )} = ( \frac{α - β}{2} , \frac{α + β + d}{2} ) .$$

If l is even, then:
If the symbol yᵢ^{(l)} has been decoded as a 0, the point is first scaled by multiplying it by

$$\frac{1}{\sqrt{2}} ,$$

shifted rightward by

$$\frac{d}{{( \sqrt{2} )}^{l}} ,$$

then shifted downwards by d/2 and, finally, rotated clockwise by 45°, namely the new symbol is given by:

$${y}_{i}^{( l + 1 )} = ( \frac{β + α}{2} , \frac{β - α - d}{2} ) .$$

If the symbol yᵢ^{(l)} has been decoded as a 1, the point is first scaled by multiplying it by

$$\frac{1}{\sqrt{2}} ,$$

shifted leftward by

$$\frac{d}{{( \sqrt{2} )}^{l}} ,$$

then shifted downwards by d/2 and finally rotated clockwise by 45°, namely the new symbol is given by:

$${y}_{i}^{( l + 1 )} = ( \frac{α - β}{2} , \frac{α + β - d}{2} ) .$$

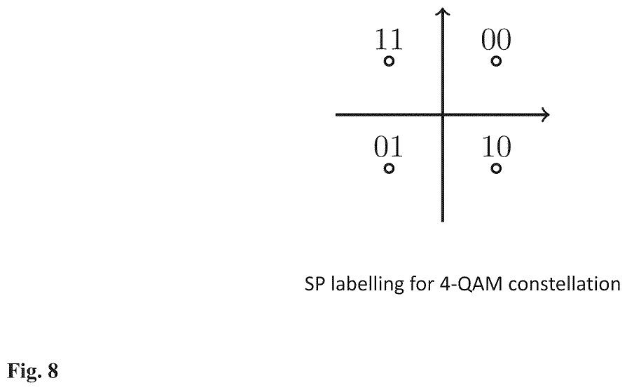

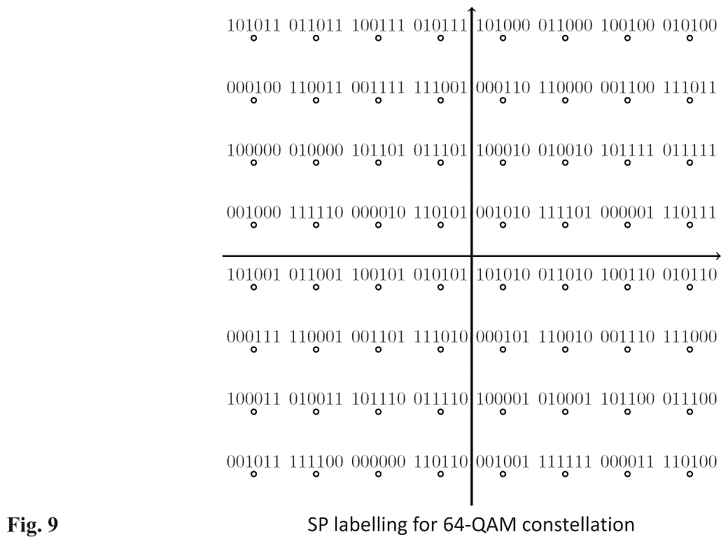

It is worth noticing that level rules may be swapped without changing the overall method, while obtaining a different labelling. For example, the rule for 0 can be applied if the symbol yᵢ^{(l)} has been decoded as a 1 and vice-versa. The proposed moving rules impose a labelling on the original QAM constellation. The constellation symbol to bit string mapping can be performed e.g. by running a hard-decision decoder following the moving rules and using the decision grid to assign bit values. FIGS. 4, 8 and 9 represent some embodiments of the proposed disclosure, namely the SP labelling for QAM constellations of different sizes induced by the above moving rules. In particular, FIG. 4 shows an example of SP labelling for a 16-QAM constellation, FIG. 8 shows an example of a SP labelling for a 4-QAM constellation and FIG. 9 shows an example of SP labelling for a 64-QAM constellation.

In the following, a method for calculating the LLRs is presented. In this example, a decision grid is used, which is always the same and does not depend on the coding level. In fact, if the procedure to change the position of the received point or symbol described previously is applied, then the overall structure of the SP grid remains the same. At each level, the only thing that changes is the boundary of the constellation. If the point or symbol is inside the boundary, the low complexity LLR calculation method proposed in the following can be applied, otherwise the classical method based on finding the nearest constellation point can be used. The number of grid points included in the boundary depends on the decoding level, namely decoding level l includes 2^{l} grid points. The shape of the boundary is given by the contour of a QAM constellation of 2^{l} points.

The decision grid has a checkerboard 0/1 structure, for example, resembles a checkboard having squares of side d. In the following, a decision grid giving the value of 0 to the square centered in point (d/2,d/2) is created. It is worth noticing that a different choice on the value provides a different labelling, however, without changing the overall idea. The described decision grid is depicted in FIG. 6. This design permits to use the same decision grid at every level, and to have a low-complexity formulation of LLR calculation. In fact, if the received point lays inside the level boundary, then the nearest constellation point can be calculated by mapping the received point to the center of the grid. For the points laying inside the boundaries of the decision grids depicted in FIG. 7, if yᵢ^{(l)}=(α,β), then, its LLR [symbol] can be calculated as follows:

$${ℓ}_{i}^{( l )} ≅ \frac{\begin{matrix}{( {[ β + α + d ]}_{2 d} - d )}^{2} + {( {[ β - α ]}_{2 d} - d )}^{2} - \\ {( {[ β + α ]}_{2 d} - d )}^{2} - {( {[ β - α + d ]}_{2 d} - d )}^{2}\end{matrix}}{4 {σ}^{2}}$$

In the above formula, [·]_{2d} represents modulo 2d truncation. If the point lies outside the boundary, the common approximation described previously can be used. However, since the grid is the same at each level, only one set of constellation points should be stored at each level, reducing the storage requirements of the de-mapper.

At the decoder 303, the proposed low-complexity de-mapper can be used. At level l, the symbol yᵢ^{(l)} may be used to calculate the LLR [symbol] using the proposed decision grid mechanism. When all symbols LLRs are calculated, they may be given to the decoder of component code for level l. After component code decoding, a bit, representing hard-decision on the l-th bit of the symbol, is associated to each symbol yᵢ^{(l)}. This bit is used, along with the parity of l, to calculate the new symbol yᵢ^{(l+1)}, and the procedure is repeated until l=m.

For example, at the decoder 303, let us suppose that d=2 and that a single point y having cartesian coordinates (−1.77,−2.40) has been received over an AWGN channel with variance σ²=0.7. This point is depicted in FIG. 5(a). In order to perform the demodulation of the first bit, if y₁^{(l)}=y, its LLR [symbol] can be calculated as:

$${ℓ}_{1}^{( 1 )} ≅ \frac{\begin{matrix}{( {[ - 2.4 - 1.77 + 2 ]}_{4} - 2 )}^{2} + {( {[ - 2.4 + 1.77 ]}_{4} - 2 )}^{2} - \\ {( {[ - 2.4 - 1.77 ]}_{4} - 2 )}^{2} - {( {[ - 2.4 + 1.77 + 2 ]}_{4} - 2 )}^{2}\end{matrix}}{2.8} = - 0.64 .$$

The LLR is negative. This value is given to the level-1 decoder, returning a value of 1. Now, the received point can be moved to:

$${y}^{′} = {y}_{1}^{( 2 )} = ( \frac{α - β}{2} , \frac{α + β + d}{2} ) = ( \frac{- 1.77 + 2.4}{2} , \frac{- 1.77 - 2.4 + 2}{2} ) = ( 0.31 , - 1.08 )$$

As depicted in FIG. 5(b), its LLR can be evaluated as:

$${ℓ}_{1}^{( 1 )} ≅ \frac{\begin{matrix}{( {[ - 1.08 + 0.31 + 2 ]}_{4} - 2 )}^{2} + {( {[ - 1.08 - 0.31 ]}_{4} - 2 )}^{2} - \\ {( {[ - 1.08 + 0.31 ]}_{4} - 2 )}^{2} - {( {[ - 1.08 - 0.31 + 2 ]}_{4} - 2 )}^{2}\end{matrix}}{2.8} = - 0.9 .$$

Again, the LLR is negative. After level-2 decoding, the second bit is evaluated as 1, and the point can be moved to:

$${y}^{″} = {y}_{1}^{( 3 )} = ( \frac{α - β}{2} , \frac{α + β - d}{2} ) = ( \frac{0.31 + 1.08}{2} , \frac{0.31 - 1.08 - 2}{2} ) = ( 0.69 , 1.38 ) .$$

The demodulation process proceeds in this way until the level-4 code has been decoded.

This SP labelling for QAM constellation permits a low-complexity de-mapping for MLC decoding. This is due to both using the same decision grid at each decoding level and calculation LLRs through a simple formula, not requiring to find the nearest constellation point. The performance of the LLR calculation is provably equivalent to the state-of-the-art minmax approach. A straight forward application for the proposed method is in the modulation of multi-level polar codes.

In this disclosure, a novel QAM labelling method is proposed which is able to solve the two drawbacks discussed in a previous section. The proposed labelling has two peculiar features. First, the same sub-constellation is used at a given decoding level for all symbols, independently of the decisions taken on the already decoded bits. More precisely, a decision grid is imposed by the proposed labelling, which remains the same for each level independently from the decisions taken at the previous levels. This feature permits to avoid keeping track of de-mapper branching, namely on the sub-constellation of every partially decoded symbol. Second, the proposed labelling ensures a checkerboard 0/1 structure at every level for the leftmost bit. In practice, the leftmost bit symbol of the unique sub-constellation at a given level is the same for all the sub-constellations at every level. If only the leftmost symbol of a sub-constellation is taken into account, the same SP labelling is used at every level, where the number of points is halved at every decoding level. This permits to keep the LLR calculation complexity small by reducing the number of comparisons for LLR calculation.

In other words, these two results are obtained by reversing the common de-mapping technique: while a standard de-mapper changes constellations while keeping the received symbol fixed, it is proposed, in this disclosure, to keep fix the constellation while changing the position of the received symbol. In practice, a received symbol is represented by a point in a Cartesian system, and de-mapping consists on finding the closest constellation point depicted in the same system. When a decision is taken on a bit of the received symbol, it is proposed to move the symbol through rotations and translations in order to find its place in the next level unique sub-constellation. These operations are simple to execute on hardware, resulting in a simpler de-mapping method compared to the state-of-the-art.

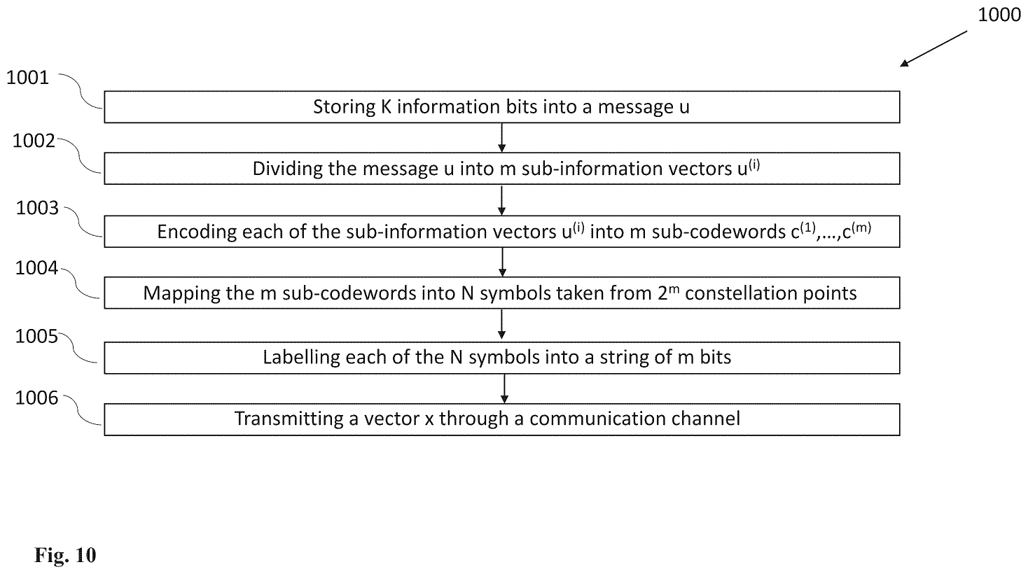

FIG. 10 shows a schematic representation of a method 1000 for a multi-stage encoder 301 according to an embodiment.

The multi-stage encoder 301 comprises m sub-encoders for encoding K information bits by means of m component codes, each of length N, in a codeword having a total length of mN. Each of m, K and N is an integer, wherein m≤N and K≤N. The method 1000 comprises a step 1001 of storing the K information bits into a message u, and a step 1002 of dividing the message u into m sub-information vectors u⁽ⁱ⁾, i=1, . . . , m of length K(1), . . . , K(m), respectively, wherein K(1)+ . . . +K(m)=K. The method 1000 further comprises a step 1003 of encoding, by means of the m sub-encoders, each of the sub-information vectors u(i) into m sub-codewords c(1), . . . , c(m), and a step 1004 of mapping the m sub-codewords c(1), . . . , c(m) into N symbols taken from 2^{m} constellation points of a modulation format to form a vector x. The method 1000 further comprises a step 1005 of labelling each of the N symbols into a string of m bits, and a step 1006 of transmitting the vector x through a communication channel.

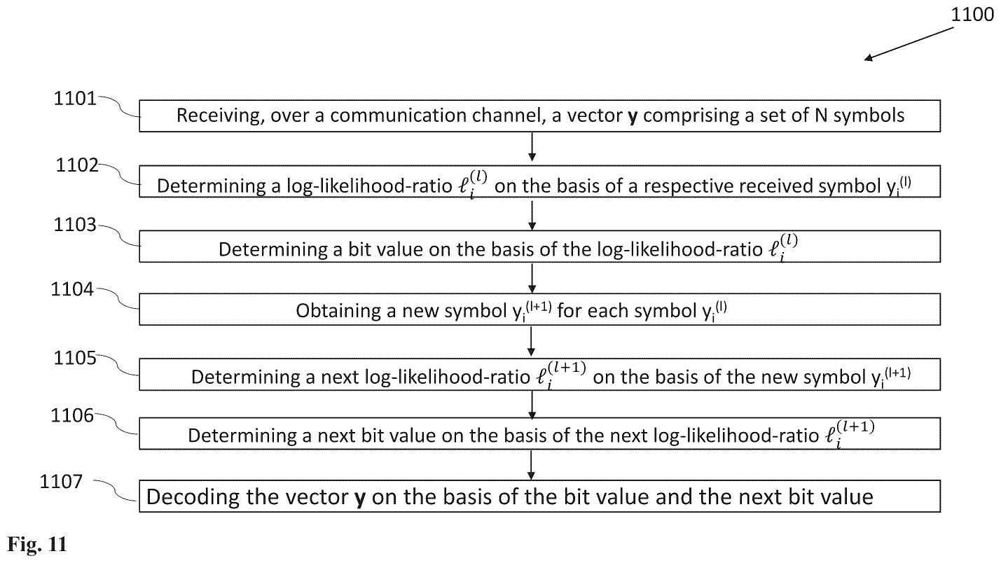

FIG. 11 shows a schematic representation of a method 1100 for a multi-stage decoder 303 according to an embodiment.

The multi-stage decoder 303 comprises m sub-decoders. The method 1100 comprises a step 1101 of receiving 1101, over a communication channel 302, a vector y comprising a set of N symbols. Each of m and N is an integer and m≤N. Further, each received symbol yi(l) corresponds to one of a set of constellation points of a bi-dimensional modulation format, wherein the set of constellation points is divided into two subsets of constellation points including a first subset assigned to a bit of value 0 and a second subset assigned to a bit of value 1, such that a minimum distance d in the same subset is maximized. The vector y has coordinates (α, β) and components yi(l), i=1, . . . , N, and l=1, . . . , m. Moreover, the method 1100 comprises a step 1102 of determining a log-likelihood-ratio [symbol] on the basis of a respective received symbol yi(l), and a step 1103 of determining 1103 a bit value on the basis of the log-likelihood-ratio [symbol] by means of a l-level sub-decoder. Further, the method 1100 comprises a step 1104 of obtaining a new symbol yi(l+1) for each symbol yi(l) on the basis of the bit value and by performing a transformation on the symbol yi(l), wherein the transformation comprises a rotation and a shift. The method 1100 also comprises a step 1105 of determining a next log-likelihood-ratio [symbol] on the basis of the new symbol yi(l+1), a step 1106 of determining a next bit value on the basis of the next log-likelihood-ratio [symbol] , and a step 1107 of decoding the vector y on the basis of the bit value and the next bit value.

The present disclosure has been described in conjunction with various embodiments as examples as well as implementations. However, other variations can be understood and effected by those persons skilled in the art and practicing the claimed matter, from the studies of the drawings, this disclosure and the independent claims. In the claims as well as in the description the word “comprising” does not exclude other elements or steps and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation.

What is claimed is:

1. A multi-stage encoder comprising m sub-encoders for encoding K information bits by means of m component codes, each component code being of length N, in a codeword having a total length of mN, wherein each of m, K and N is an integer, wherein m≤N and K≤N, and wherein the encoder is configured to:
store the K information bits into a message u;
divide the message u into m sub-information vectors u⁽ⁱ⁾, i=1, . . . , m of length K⁽¹⁾, . . . , K^{(m)}, respectively, wherein K⁽¹⁾+ . . . +K^{(m)}=K;
encode, by means of the m sub-encoders, each of the m sub-information vectors u⁽ⁱ⁾ into m sub-codewords c⁽¹⁾, . . . , c^{(m)};
map the m sub-codewords c⁽¹⁾, . . . , c^{(m)} into N symbols taken from 2^{m} constellation points of a modulation format to form a vector x;
label each of the N symbols into a string of m bits; and
transmit the vector x through a communication channel.

2. The encoder of claim 1, wherein the encoder is configured to label each of the N symbols into the string of m bits as follows: if a first constellation point A has coordinates (α, β),
determine a sign S_{A} of the first constellation point A;
assign a first bit value to a label of the point A as 0 or 1 depending on the sign S_{A};
then, for i=1, . . . , m−1
determine coordinates of a second constellation point Aⁱ=(αⁱ, βⁱ) on the basis of i+1 and a i^{th} bit value, wherein the 1^{st} bit value is the first bit value;
determine a sign S_{Ai} of the second constellation point Aⁱ;
determine a (i+1)^{th} bit value on the basis of sign S_{Ai}; and
assign the (i+1)^{th} bit value to the label of the point A.

3. The encoder of claim 2, wherein the coordinates (α, β) and (αⁱ, βⁱ) are Cartesian coordinates.

4. The encoder of claim 2, wherein the encoder is further configured to determine the sign S_{A} of the first constellation point A on the basis of the following formula:
$${s}_{A} = sign ( {( {[ β + α + d ]}_{2 d} - d )}^{2} + {( {[ β - α ]}_{2 d} - d )}^{2} - {( {[ β + α ]}_{2 d} - d )}^{2} - {( {[ β - α + d ]}_{2 d} - d )}^{2} ) ,$$
wherein d is a distance of the constellation points.

5. The encoder of claim 2, wherein, for i=1, the encoder is configured to calculate the coordinates (α¹, β¹) of the second constellation point A¹ on the basis of the following formula:
$${α}^{1} = \{ \begin{matrix}\frac{α + β}{2} if a = 0 , i is even \\ \frac{α + β}{2} if a = 0 , i is odd \\ \frac{α - β}{2} if a = 1 , i is even \\ \frac{α + β}{2} if a = 1 , i is odd\end{matrix} , {β}^{1} = \{ \begin{matrix}\frac{β - α + d}{2} if a = 0 , i is even \\ \frac{β - α - d}{2} if a = 0 , i is odd \\ \frac{α + β + d}{2} if a = 1 , i is even \\ \frac{α + β - d}{2} if a = 1 , i is odd\end{matrix}$$
wherein a represents a value of a previously assigned bit.

6. The encoder of claim 1, wherein the constellation points are of a 2^{m} quadrature amplitude modulation bi-dimensional modulation format, where m is an even number.

7. A multi-stage decoder comprising m sub-decoders, the decoder being configured to:
receive, over a communication channel (302), a vector y comprising a set of N symbols, wherein each of m and N is an integer and m≤N, wherein each received symbol yᵢ^{(l)} corresponds to one of a set of constellation points of a bi-dimensional modulation format, wherein the set of constellation points is divided into two subsets of constellation points including a first subset assigned to a bit of value 0 and a second subset assigned to a bit of value 1, such that a minimum distance d in the same subset is maximized, and wherein the vector y has coordinates (α, β) and components yᵢ^{(l)}, i=1, . . . , N, and l=1, . . . , m;
determine a log-likelihood-ratio [symbol] on the basis of a respective received symbol yᵢ^{(l)};
determine a bit value on the basis of the log-likelihood-ratio lᵢ^{(l)} by means of a l-level sub-decoder;
obtain a new symbol yᵢ^{(l+1)} for each symbol yᵢ^{(l)} on the basis of the bit value and by performing a transformation on the symbol yᵢ^{(l)}, wherein the transformation comprises a rotation and a shift;
determine a next log-likelihood-ratio [symbol] on the basis of the new symbol yᵢ^{(l+1)};
determine a next bit value on the basis of the next log-likelihood-ratio [symbol] ; and
decode the vector y on the basis of the bit value and the next bit value.

8. The decoder of claim 7, wherein the constellation points are of a 2^{m} quadrature amplitude modulation bi-dimensional modulation format, where m is an even number.

9. The decoder of claim 7, wherein the decoder is configured to generate a decision grid as a Cartesian plane partition, wherein a center of a square of the decision grid represents a constellation symbol.

10. The decoder of claim 7, wherein the decoder is further configured to calculate the new symbol yᵢ^{(l+1)} on the basis of the received symbol yᵢ^{(l)}=(α, β), wherein (α,β) are coordinates of the received symbol yᵢ^{(l)},
wherein, if l is odd, then:
If the received symbol yᵢ^{(l)} has been decoded as a 0, then
$${y}_{i}^{( l + 1 )} = ( \frac{β + α}{2} , \frac{β - α + d}{2} ) ;$$
If the received symbol yᵢ^{(l)} has been decoded as a 1, then
$${y}_{i}^{( l + 1 )} = ( \frac{α - β}{2} , \frac{α + β + d}{2} ) ,$$
and
wherein, if l is even, then:
If the received symbol yᵢ^{(l)} has been decoded as a 0, then
$${y}_{i}^{( l + 1 )} = ( \frac{β + α}{2} , \frac{β - α - d}{2} ) ;$$
If the received symbol yᵢ^{(l)} has been decoded as a 1, then
$${y}_{i}^{( l + 1 )} = ( \frac{α - β}{2} , \frac{α + β - d}{2} ) .$$

11. The decoder of claim 7, wherein the decoder is further configured to calculate the log-likelihood-ratio [symbol] as:
$${ℓ}_{i}^{( l )} ≅ \frac{\begin{matrix}{( {[ β + α + d ]}_{2 d} - d )}^{2} + {( {[ β - α ]}_{2 d} - d )}^{2} - \\ {( {[ β + α ]}_{2 d} - d )}^{2} - {( {[ β - α + d ]}_{2 d} - d )}^{2}\end{matrix}}{4 {σ}^{2}} ,$$
wherein [·]_{2d} represents a modulo 2d truncation and σ represents a channel variance.

12. A method for a multi-stage encoder comprising m sub-encoders for encoding K information bits by means of m component codes, each of length N, in a codeword having a total length of mN, wherein each of m, K and N is an integer, wherein m≤N and K≤N, and wherein the method comprises:
storing the K information bits into a message u;
dividing the message u into m sub-information vectors u⁽ⁱ⁾, i=1, . . . , m of length K⁽¹⁾, . . . , K^{(m)}, respectively, wherein K⁽¹⁾+ . . . +K^{(m)}=K;
encoding, by means of the m sub-encoders, each of the m sub-information vectors u⁽ⁱ⁾ into m sub-codewords c⁽¹⁾, . . . , c^{(m)};
mapping the m sub-codewords c⁽¹⁾, . . . , c^{(m)} into N symbols taken from 2^{m} constellation points of a modulation format to form a vector x;
labelling each of the N symbols into a string of m bits; and
transmitting the vector x through a communication channel.

13. The method of claim 12, wherein the step of labelling each of the N symbols into a string of m bits comprises:
if a first constellation point A has coordinates (α, β),
determining a sign S_{A} of the first constellation point A;
assigning a first bit value to a label of the point A as 0 or 1 depending on the sign S_{A};
then, for i=1, . . . , m−1
determining coordinates of a second constellation point Aⁱ=(αⁱ, βⁱ) on the basis of i+1 and a i^{th} bit value, wherein the 1st bit value is the first bit value;
determining a sign S_{Ai} of the second constellation point Aⁱ;
determining a (i+1)^{th} bit value on the basis of sign S_{Ai}; and
assigning the (i+1)^{th} bit value to the label of the point A.

14. The method of claim 13, wherein the coordinates (α, β) and (αⁱ, βⁱ) are Cartesian coordinates.

15. The method of claim 13, wherein the step of determining the sign S_{A} of the first constellation point A comprises: determining the sign S_{A} of the first constellation point A on the basis of the following formula:
$${s}_{A} = sign ( {( {[ β + α + d ]}_{2 d} - d )}^{2} + {( {[ β - α ]}_{2 d} - d )}^{2} - {( {[ β + α ]}_{2 d} - d )}^{2} - {( {[ β - α + d ]}_{2 d} - d )}^{2} ) ,$$
wherein d is a distance of the constellation points.

16. The method of claim 13, wherein the method further comprises, for i=1, calculating the coordinates (α¹, β¹) of the second constellation point A¹ on the basis of the following formula:
$${α}^{1} = \{ \begin{matrix}\frac{α + β}{2} if a = 0 , i is even \\ \frac{α + β}{2} if a = 0 , i is odd \\ \frac{α - β}{2} if a = 1 , i is even \\ \frac{α + β}{2} if a = 1 , i is odd\end{matrix} , {β}^{1} = \{ \begin{matrix}\frac{β - α + d}{2} if a = 0 , i is even \\ \frac{β - α - d}{2} if a = 0 , i is odd \\ \frac{α + β + d}{2} if a = 1 , i is even \\ \frac{α + β - d}{2} if a = 1 , i is odd\end{matrix}$$
wherein a represents a value of a previously assigned bit.

17. The method of claim 12, wherein the constellation points are of a 2^{m} quadrature amplitude modulation bi-dimensional modulation format, where m is an even number.
